(19) United States
(12) Patent Application Publication
(10) Pub. No.: US 2013/0154653 A1
(43) Pub. Date: Jun. 20, 2013

(54) ADAPTIVE METHOD FOR DETERMINING THE POWER THAT CAN BE MAXIMALLY OUTPUTTED OR ABSORBED BY A BATTERY

(71) Applicants: Andre Boehm, Kornwestheim (DE); Jochen Weber, Markgroeningen (DE)

(72) Inventors: Andre Boehm, Kornwestheim (DE); Jochen Weber, Markgroeningen (DE)

(73) Assignee: Robert Bosch GmbH, Stuttgart (DE)

(21) Appl. No.: 13/576,743

(22) PCT Filed: Jan. 3, 2011
(86) PCT No.: PCT/EP2011/050024

§ 371 Date: Oct. 22, 2012

(30) Foreign Application Priority Data
Feb. 3, 2010 (DE) 102010001529.6

(51) Int. Cl. G01R 31/36

(52) U.S. Cl. CPC G01R 31/3606
USPC 324/426

(57) ABSTRACT

A method for determining the power that can be provided or absorbed by a battery includes determining a state variable of the battery. A power that can be provided or absorbed by the battery during a specified load period is determined using a table of power values and the state variable of the battery. The state variable of the battery is used as an access parameter for the table. A load of the battery is measured using an operating parameter of the battery. A load period in which the load of the battery is given is measured. The measured load period is compared with a comparison range that contains the specified load period. A correction routine is carried out if the load period lies in the comparison range. A battery system includes a controller for carrying out the method. A motor vehicle includes the battery system.

### PRIOR ART

The invention relates to a method for determining the power that can be provided or absorbed by a battery, a battery system which is designed to implement the method, and a motor vehicle with such a battery system.

In hybrid and electric vehicles, batteries involving lithium-ion or NiMH technology are used which have a large number of electrochemical battery cells connected in series. A battery management system is used for monitoring the battery and is intended to provide as long a life as possible, in addition to safety monitoring. For this purpose, the voltage of each individual battery cell together with the battery current and the battery temperature is measured and a state estimation (for example of the state of charge or the state of ageing of the battery) is performed. In order to maximize the life, it is expedient to identify at any time the maximum power capacity provided at that time of the battery, i.e. the maximum electrical power that can be output or absorbed. If this power capacity is exceeded, the ageing of the battery can be accelerated considerably.

The operating range of an electrochemical energy store can be characterized as a multi-dimensional space which is formed by state variables such as temperature, state of charge or current intensity, for example. Numerous methods are known from the prior art which are intended to simulate the response of a battery under the respectively provided loads and state variables and are thus intended to model this response for battery management. One method is to store power or energy values of the electrochemical energy store in a multi-dimensional table, which corresponds to the operating range. In order to set up such a table, complex detailed measurement of the properties of the energy store is required in a laboratory and, in general, neither variations in the properties of the batteries owing to production variance or as a result of ageing are taken into consideration. A second approach is based on simulating the electrochemical energy store by a suitable simulation model, whose parameters are matched to the real response. A state prediction can then be made with the aid of this model and the known parameters. One disadvantage with this method is that the complex response of electrochemical energy stores is sometimes nonlinear and can therefore only be described insufficiently by simple models. Complex models, on the other hand, have a high number of free parameters, whose precise and independent determination is associated with considerable problems.

### DISCLOSURE OF THE INVENTION

A first aspect of the invention therefore introduces a simple and robust method for determining the power that can be provided or absorbed by a battery. The method can be used, for example, in addition to other methods known from the prior art, as a fallback solution or for plausibility checking of results of such a method. The method comprises the following steps:
determination of a state variable of the battery, in particular a battery temperature and/or a state of charge;
determination of a power that can be provided or absorbed by the battery during at least one predetermined load time period on the basis of a table of power values and the state variable of the battery, the state variable of the battery acting as access parameter for the table;
measurement of a load on the battery on the basis of an operational parameter of the battery, in particular a battery current and/or a battery voltage;
measurement of a load time period in which the load on the battery is provided;
comparison of the measured load time period with a comparison region which contains the predetermined load time period; and
implementation of a correction routine when the load time period is in the comparison region.

The correction routine comprises at least comparison of the power value from the table and the measured load, determination of a correction value for the power value from the table on the basis of a result of the comparison of the power value from the table and the measured load, and correction of the power value from the table on the basis of the correction value.

The method of the invention can reproduce the response of a battery, which changes as the battery ages, in a table in a simple manner. In this case, it is of comparatively little relevance whether the power values stored at the outset in the table represent a good reproduction of reality since they are adjusted with the actually observed values and are simulated depending on the degree of discrepancy. The observation of the response of the battery is performed on the basis of predetermined load cases, for example the withdrawal or supply of power pulses over one second or ten seconds. In this case, the table preferably has maximum powers that can be withdrawn from or supplied to the battery over a corresponding time period without the battery cells of the battery falling below or exceeding the minimum or maximum permissible voltage values during the withdrawal or charging time period. If a specific power is withdrawn from or supplied to the battery for a determined time period, the similarity of the load case with respect to the predetermined load case(s) is determined (in particular the duration and intensity of the load). Then, the similarity of the predicted response of the battery (for example the depth of the dip in the battery voltage caused by a withdrawal) is compared with the actually measured response. From the two comparisons, a correction value is derived that is applied to the table entry respectively used for the prediction of the battery response.

The power values stored in the table can thus be matched to the actual response of the battery with little computation complexity. The method according to the invention manages without any complex and possibly faulty or incomplete models. Since the method continuously adjusts the detected power values with reality, it automatically learns the response of the ageing battery and is therefore very robust with respect to faults on the basis of unknown or unconsidered properties of the battery.

In a preferred variant of the method, the operational parameter of the battery comprises the battery voltage. The determined correction value is in this case dependent on a difference between the battery voltage at the end of the load time period and a minimum or maximum permissible battery voltage, in particular 2.8 V or 4.2 V, respectively. In this case, the correction value is determined depending on the difference between the battery voltage (or cell voltage) and the minimum or maximum permissible voltage for the battery cell. The smaller the difference, the more precisely the power values from the table, which specify a maximum power to be withdrawn or supplied, correspond to reality, for which reason the correction value also needs to be even lower. This adaptive determination of the correction value has the advantage that the power values from the table quickly and continuously come close to a value which correctly describes reality. 2.8 and 4.2 V are the minimum and maximum permissible cell voltages, respectively, for a lithium-ion cell. When using other battery technologies, other voltages can be applied correspondingly.

The specific operational parameter of the battery can also comprise the battery current. The determined correction value is then preferably dependent on a difference between the battery current over the load time period and a maximum permissible battery current in the charging or discharging direction. In an equivalent manner to the above-described case, a load case can therefore also be defined via the battery current, with the result that the actually flowing battery current is also used for the determination of the correction value for the comparison.

The determined correction value can also be dependent on a difference between the power value from the table and the measured load on the battery. In this case, the electrical power output by the battery is measured, for example, by simultaneous measurement of the battery current and the battery voltage. The correction value is then dependent on the difference between the value predicted by the table and the actual power value. This means that the correction is always greater, the further the prediction was from reality.

The correction routine of the method can comprise an additional step of correcting further power values from the table which, in the table, are adjacent to the power value from the table, on the basis of the correction value. This method variant has the advantage that it is not necessary for each load case associated with a table entry to occur in order to obtain updated power values which are adjusted to reality. In this case, it is also conceivable for all values given for a specific state variable of the battery or combination of state variables to be corrected simultaneously by using the correction value, which has the advantage that a large number of power values from the table are updated quickly by measurements of real load cases. If, on the other hand, only determined, adjacent power values from the table are corrected, it is however ensured that at least similar boundary conditions apply to these as to the actually occurred case, which results in more accurate tracking of the table values closer to the actual properties of the battery.

In this case, the correction value can be weighted for each further power value, wherein a gap between the respective further power value and the power value from the table is taken into consideration. The further removed a power value from the table to be corrected is from table entry the closest to the actual load case, the less significance the actual load case has for this power value. Correspondingly, the correction value has a lower weighting the further the power value to be corrected is removed from the closest table entry.

A second aspect of the invention relates to a battery system with a battery and a battery management unit, which is connected to the battery and has at least a current measurement unit, a voltage measurement unit, a temperature sensor and a controller. The current measurement unit is designed to measure a battery current of the battery. The voltage measurement unit is designed to measure a battery voltage of the battery. The temperature sensor is designed to measure a temperature of the battery. The controller is connected to the current measurement unit, the voltage measurement unit and the temperature sensor and is designed to implement the method in accordance with the first aspect of the invention.

A third aspect of the invention introduces a motor vehicle with an electric drive motor for moving the motor vehicle and a battery system in accordance with the second aspect of the invention, connected to the electric drive motor.

### DRAWINGS

### Brief Description of the Figures

The invention will be explained in more detail below with reference to figures of exemplary embodiments, in which:

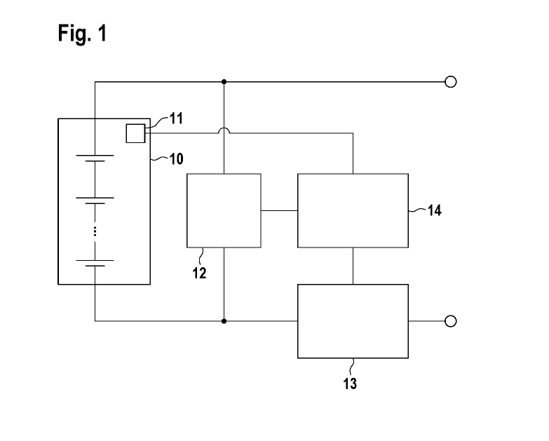

FIG. 1 shows an exemplary embodiment of a battery system according to the invention; and

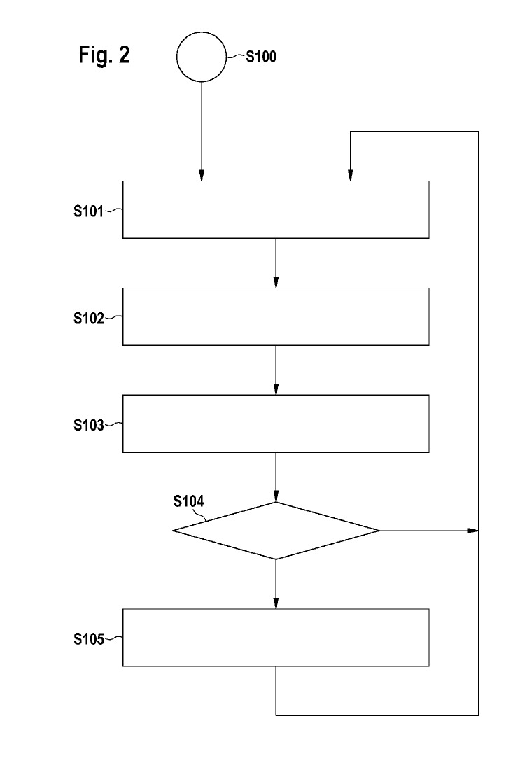

FIG. 2 shows an exemplary embodiment of a method according to the invention.

### DETAILED DESCRIPTION OF THE FIGURES

FIG. 1 shows an exemplary embodiment of a battery system according to the invention. A battery 10 is equipped with a temperature sensor 11, which is arranged with the greatest possible physical proximity to at least one battery cell of the battery 10. A voltage measurement unit 12, which measures the respectively given battery voltage, is connected to the two battery terminals of the battery 10. A current measurement unit 13 which measures the battery current flowing through the battery 10 is arranged in one of the current paths of the battery. The current measurement unit 13 can be in the form of, for example, a nonreactive resistor with a small, precisely known size and a second voltage measurement unit or else a Hall sensor. Temperature sensor 11, voltage measurement unit 12 and current measurement unit 13 are connected to a controller 14, which monitors and characterizes the response of the battery 10 by virtue of it implementing the method according to the invention for determining the power that can be provided or absorbed by a battery.

FIG. 2 shows an exemplary embodiment of a method according to the invention. The method starts with step S100. In step S101, a state variable of the battery, in particular a battery temperature and/or a state of charge, is determined. The state variable of the battery is used in step S102 for determining a power that can be provided or absorbed by the battery during a predetermined load time period on the basis of a table of power values and the state variable of the battery as access parameter for the table. In the following step 103, a load on the battery is measured on the basis of an operational parameter of the battery, in particular a battery current and/or a battery voltage, while at the same time a load time period is measured in which the load on the battery is provided. In the subsequent step S104, the measured load time period is compared with a comparison region, which contains the predetermined load time period. In this way, it is established whether an actual load case which is similar to the load case recorded in the table has occurred. When the load time period is in the comparison region, in step S105 a correction routine is implemented. Otherwise, no significant load case has occurred, for which reason the system branches back to the beginning of the method in step S101. The correction routine in step S105 comprises at least comparison of the power value from the table and the measured load, determination of a correction value for the power value from the table on the basis of a result of the comparison of the power value from the table and the measured load, and correction of the power value from the table on the basis of the correction value.

1. A method for determining the power that can be provided or absorbed by a battery, comprising:
determining a state variable of the battery;
determining a power that can be provided or absorbed by the battery during a predetermined load time period on the basis of a table of power values and the state variable of the battery, the state variable of the battery acting as access parameter for the table;
measuring a load on the battery on the basis of an operational parameter of the battery;
measuring a load time period in which the load on the battery is provided;
comparing the measured load time period with a comparison region which contains the predetermined load time period; and
implementing a correction routine when the load time period is in the comparison region;
wherein the correction routine comprises:
at least comparing the power value from the table and the measured load,
determining a correction value for the power value from the table on the basis of a result of the comparison of the power value from the table and the measured load, and
correcting the power value from the table on the basis of the correction value.

2. The method from claim 1, wherein the operational parameter of the battery comprises the battery voltage, and wherein the determined correction value is dependent on a difference between the battery voltage at the end of the load time period and a minimum or maximum permissible battery voltage.

3. The method from claim 1, wherein the operational parameter of the battery comprises the battery current, and wherein the determined correction value is dependent on a difference between the battery current over the load time period and a maximum permissible battery current in the charging or discharging direction.

4. The method from claim 1, wherein the determined correction value is dependent on a difference between the power value from the table and the measured load on the battery.

5. The method from claim 1, correction routine further comprising correcting further power values from the table which, in the table, are adjacent to the power value from the table, on the basis of the correction value.

6. The method from claim 5, wherein the correction value is weighted for each further power value, and wherein a gap between the respective further power value and the power value from the table is taken into consideration.

7. A battery system, comprising:
a battery, and
a battery management unit connected to the battery, the battery management unit including:
at least one current measurement unit which is configured to measure a battery current of the battery,
a voltage measurement unit which is configured to measure a battery voltage of the battery,
a temperature sensor which is configured to measure a temperature of the battery, and
a controller which is connected to the current measurement unit, the voltage measurement unit, and the temperature sensor, the controller being configure to:
determine a state variable of the battery,
determine a power that can be provided or absorbed by the battery during a predetermined load time period on the basis of a table of power values and the state variable of the battery, the state variable of the battery acting as access parameter for the table,
measure a load on the battery on the basis of an operational parameter of the battery,
measure a load time period in which the load on the battery is provided,
compare the measured load time period with a comparison region which contains the predetermined load time period, and
implement a correction routine when the load time period is in the comparison region,
wherein the correction routine comprises:
at least comparing the power value from the table and the measured load,
determining a correction value for the power value from the table on the basis of a result of the comparison of the power value from the table and the measured load, and
correcting the power value from the table on the basis of the correction value.

8. A motor vehicle, comprising:
an electric drive motor configured to move the motor vehicle, and
a battery system connected to the electric drive motor, the battery system including:
a battery, and
a battery management unit connected to the battery, the battery management unit including:
at least one current measurement unit which is configured to measure a battery current of the battery,
a voltage measurement unit which is configured to measure a battery voltage of the battery,
a temperature sensor which is configured to measure a temperature of the battery, and
a controller which is connected to the current measurement unit, the voltage measurement unit, and the temperature sensor, the controller being configure to:
determine a state variable of the battery,
determine a power that can be provided or absorbed by the battery during a predetermined load time period on the basis of a table of power values and the state variable of the battery, the state variable of the battery acting as access parameter for the table,
measure a load on the battery on the basis of an operational parameter of the battery,
measure a load time period in which the load on the battery is provided,
compare the measured load time period with a comparison region which contains the predetermined load time period, and
implement a correction routine when the load time period is in the comparison region,
wherein the correction routine comprises:
at least comparing the power value from the table and the measured load,
determining a correction value for the power value from the table on the basis of a result of the comparison of the power value from the table and the measured load, and
correcting the power value from the table on the basis of the correction value.

9. The method from claim 1, wherein the state variable of the battery is one or more of a battery temperature and a state of charge.

10. The method from claim 2, wherein the minimum or maximum permissible battery voltage is 2.8 V or 4.2 V, respectively.
